(19) United States
(12) Patent Application Publication
(10) Pub. No.: US 2026/0150551 A1
(43) Pub. Date: May 28, 2026

(54) DISPLAY DEVICE

(71) Applicant: Magnolia White Corporation, Tokyo (JP)

(72) Inventors: Ryota TAKASAKI, Tokyo (JP); Hiroshi TABATAKE, Tokyo (JP); Sho YANAGISAWA, Tokyo (JP); Yozo NAKAYASU, Tokyo (JP)

(73) Assignee: Magnolia White Corporation, Tokyo (JP)

(21) Appl. No.: 19/399,687

(22) Filed: Nov. 25, 2025

(30) Foreign Application Priority Data
Nov. 25, 2024 (JP) 2024-204637

(51) Int. Cl. H10K 59/80; G06F 3/044; H10K 59/12; H10K 59/40

(52) U.S. Cl. CPC H10K 59/871; G06F 3/0448; H10K 59/1201; H10K 59/40

(57) ABSTRACT

According to one embodiment, a display device includes a display area including subpixels, a rib layer having pixel apertures, a partition surrounding each of the apertures, display elements respectively provided in the subpixels and each including an organic layer, first sealing layers respectively covering the display elements, and a touch detection electrode having light-shielding properties. The partition includes first and second segments separated by a first slit, and a connection portion crossing the first slit to connect the segments. The touch detection electrode overlaps the connection portion in plan view.

### CROSS-REFERENCE TO RELATED APPLICATIONS

This application is based upon and claims the benefit of priority from Japanese Patent Application No. 2024-204637, filed Nov. 25, 2024, the entire contents of which are incorporated herein by reference.

FIELD

Embodiments described herein relate generally to a display device.

### BACKGROUND

Recently, display devices with organic light-emitting diodes (OLED) applied thereto as display elements have been put into practical use. In this type of display devices, a technique for improving the yield is required.

### BRIEF DESCRIPTION OF THE DRAWINGS

FIG. 1 is a view showing a configuration example of a display device according to the first embodiment.

FIG. 2 is a schematic plan view showing an example of the layout of subpixels.

FIG. 3 is a schematic cross-sectional view of the display device along III-III line of FIG. 2.

FIG. 4 is a schematic plan view showing some elements of the display device according to the first embodiment.

FIG. 5 is a schematic plan view showing configuration examples applicable to a partition, a sealing layer, and a touch detection electrode according to the first embodiment.

FIG. 6 is a schematic cross-sectional view of the display device along VI-VI line of FIG. 5.

FIG. 7 is a schematic cross-sectional view of the display device along VII-VII line of FIG. 5.

FIG. 8 is a schematic plan view showing configuration examples applicable to a partition, a sealing layer, and a touch detection electrode according to the second embodiment.

FIG. 9 is a schematic plan view showing configuration examples applicable to a partition, a sealing layer, and a touch detection electrode according to the third embodiment.

FIG. 10 is a schematic plan view showing configuration examples applicable to a partition, a sealing layer, and a touch detection electrode according to the fourth embodiment.

FIG. 11A is a schematic cross-sectional view showing a configuration applicable to a display device according to the fourth embodiment.

FIG. 11B is a schematic cross-sectional view showing another configuration applicable to a display device according to the fourth embodiment.

FIG. 11C is a schematic cross-sectional view showing still another configuration applicable to a display device according to the fourth embodiment.

FIG. 12 is a schematic plan view showing configuration examples applicable to a partition, a sealing layer, and a touch detection electrode according to the fifth embodiment.

FIG. 13A is a schematic cross-sectional view showing a configuration applicable to a display device according to the fifth embodiment.

FIG. 13B is a schematic cross-sectional view showing another configuration applicable to a display device according to the fifth embodiment.

FIG. 13C is a schematic cross-sectional view showing still another configuration applicable to a display device according to the fifth embodiment.

### DETAILED DESCRIPTION

In general, according to one embodiment, a display device includes a display area including a plurality of subpixels, a rib layer having a plurality of pixel apertures respectively located in the plurality of subpixels, a partition surrounding each of the plurality of pixel apertures and including a conductive lower portion provided above the rib layer and an upper portion having an end portion protruding relative to a side surface of the lower portion, a plurality of display elements respectively provided in the plurality of subpixels and each including an organic layer emitting light in response to a voltage application, a plurality of first sealing layers formed of inorganic insulating materials and respectively covering the plurality of display elements, and a touch detection electrode having light-shielding properties, provided above the partition and configured to detect operations with respect to the detection area. The partition includes a first segment and a second segment separated from each other by a first slit, and a connection portion crossing the first slit to connect the first segment and the second segment to each other. The touch detection electrode overlaps the connection portion in plan view.

According to another aspect of the embodiment, a display device includes a display area including a plurality of subpixels, a rib layer having a plurality of pixel apertures respectively located in the plurality of subpixels, a partition surrounding each of the plurality of pixel apertures and including a conductive lower portion provided above the rib layer and an upper portion having an end portion protruding relative to a side surface of the lower portion, a plurality of display elements respectively provided in the plurality of subpixels and each including an organic layer emitting light in response to a voltage application, a plurality of first sealing layers formed of inorganic insulating materials and respectively covering the plurality of display elements, and a touch detection electrode having light-shielding properties, provided above the partition and configured to detect operations with respect to the display area. Further, the touch detection electrode has a shape entirely overlapping the partition in plan view.

The configuration of each embodiment can improve the yield of a display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. Z-direction is a normal to the plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

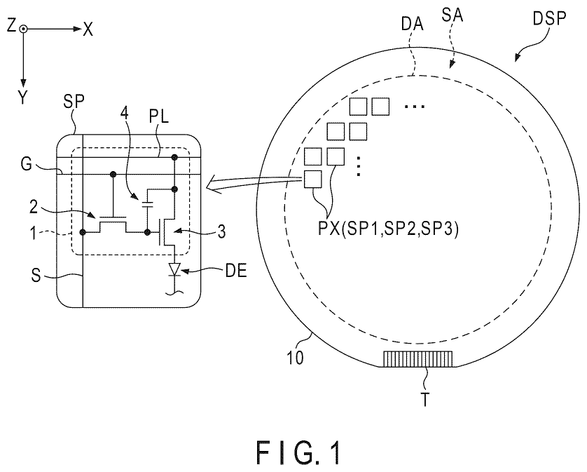

FIG. 1 is a view showing a configuration example of a display device DSP according to the first embodiment. The display device DSP comprises an insulating substrate 10. The substrate 10 has a display area DA for displaying images and a surrounding area SA around the display area DA. The substrate 10 may be glass or a resinous film having flexibility.

In the present embodiment, each of the substrate 10 and the display area DA has a circular shape in plan view. The shape of each of the substrate 10 and the display area DA in plan view is not limited to the circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP displaying different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit board applying voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines G supplying a scanning signal to the pixel circuit 1 of each subpixel SP, a plurality of signal lines S supplying a video signal to the pixel circuit 1 of each subpixel SP, and a plurality of power lines PL are provided in the display area DA. In the example of FIG. 1, the scanning lines G and the power lines PL extend in the X direction, and the signal line S extends in the Y direction. The configuration is not limited to this example.

A gate electrode of the pixel switch 2 is connected to the scanning line G. One of a source electrode and a drain electrode of the pixel switch 2 is connected to the signal line S. The other is connected to a gate electrode of the drive transistor 3 and the capacitor 4. In the drive transistor 3, one of a source electrode and a drain electrode is connected to the power line PL and the capacitor 4. The other is connected to the display element DE.

The configuration of the pixel circuit 1 is not limited to the example of the figure. For example, the pixel circuit 1 may comprise more thin-film transistors and capacitors.

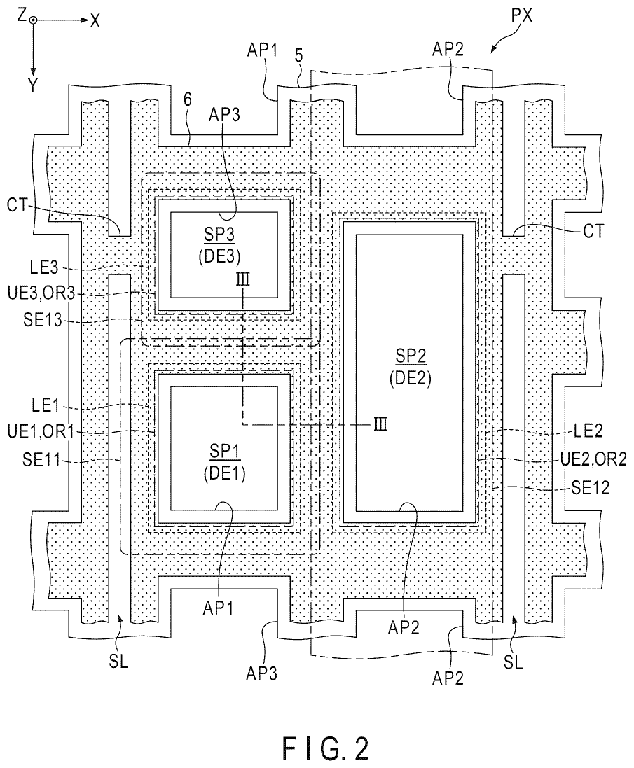

FIG. 2 is a schematic plan view showing an example of the layout of the subpixels SP1, SP2, and SP3 which constitute one pixel PX. In the example of FIG. 2, the subpixels SP1 and SP3 are arranged in the Y-direction. Further, the subpixels SP1 and SP3 are aligned with the subpixel SP2 in the X direction.

When the subpixels SP1, SP2, and SP3 are arranged in this layout, in the display area DA, a column in which the subpixels SP1 and SP3 are alternately arranged in the Y direction and a column in which the plurality of subpixels SP2 are repeatedly arranged in the Y direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, each of the pixel apertures AP1, AP2, and AP3 has a rectangular shape. The planar size of the pixel aperture AP1 is greater than the pixel aperture AP3. The planar size of the pixel aperture AP2 is greater than the pixel aperture AP1. The shape of the pixel apertures AP1, AP2, and AP3 is not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

The lower electrode LE1, the upper electrode UE1, and the organic layer OR1 constitute a display element DE1 of the subpixel SP1. The lower electrode LE2, the upper electrode UE2, and the organic layer OR2 constitute a display element DE2 of the subpixel SP2. The lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 is provided above the rib layer 5. The partition 6 functions as lines applying common voltage to the upper electrodes UE1, UE2, and UE3. The partition 6 entirely overlaps the rib layer 5 and has the same planar shape as the rib layer 5. The partition 6 surrounds the subpixels SP1, SP2, and SP3.

The partition 6 has a plurality of slits SL extending in the Y-direction. In the example of FIG. 2, the subpixels SP1, SP2, and SP3 constituting one pixel PX are provided between two slits SL in the X-direction.

Further, the partition 6 has a connection portion CT connecting parts separated from each other by the slit SL (segments to be described later). The arrangement of the slit SL and the connection portion CT are not limited to the example of FIG. 2. For example, the connection portion CT may not be provided in some slits SL.

Sealing layers SE11, SE12, and SE13 are provided in the respective subpixels SP1, SP2, and SP3. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3. For example, the sealing layer SE12 is formed continuously across the plurality of subpixels SP2 arranged in the Y-direction. In another example, the sealing layers SE12 that are spaced apart from each other may be provided for the respective subpixels SP2.

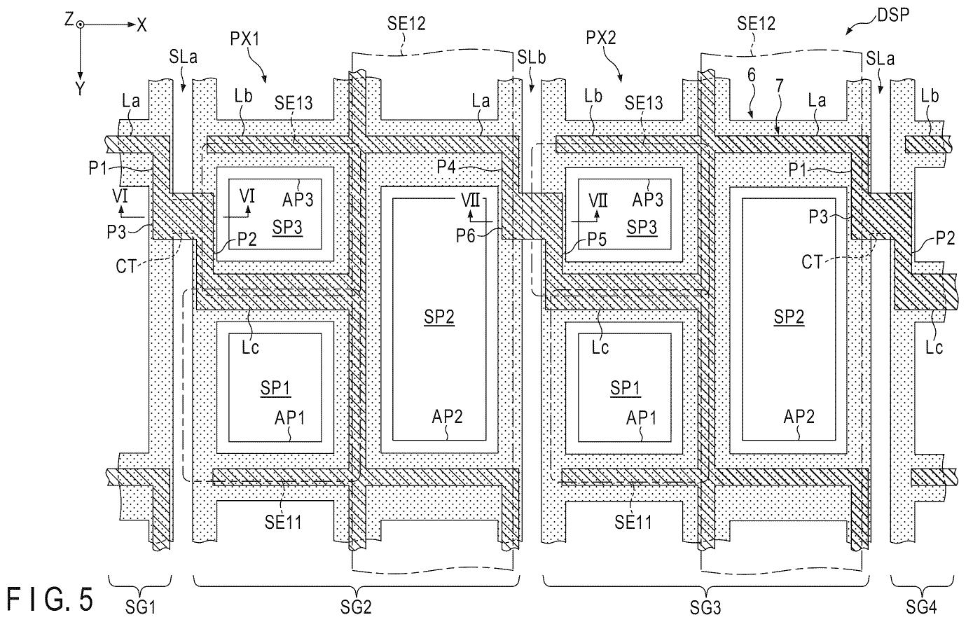

In the example of FIG. 2, part of the end portion of the sealing layer SE11 overlaps the slit SL. In contrast, the end portions of the sealing layers SE12 and SE13 entirely overlap the partition 6. As in the configuration to be described later with reference to FIG. 5, there may be provided the sealing layer SE11 whose end portion does not overlap the slit SL in its entire circumference and the sealing layer SE13 whose part of the end portion overlaps the slit SL. Further, part of the end portion of the sealing layer SE12 may overlap the slit SL.

Further, in the example of FIG. 2, the end portions of the sealing layers SE11 and SE12 overlap together, the end portions of the sealing layers SE11 and SE13 overlap together, and the end portions of the sealing layers SE12 and SE13 overlap together. In another example, the end portions of the sealing layers SE11, SE12, and SE13 may be spaced apart from each other.

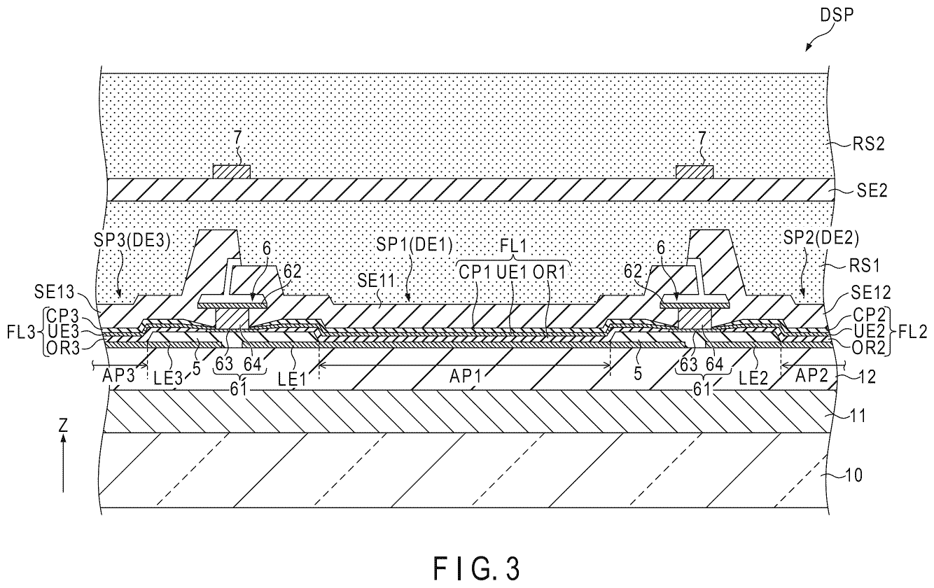

FIG. 3 is a schematic cross-sectional view of the display device DSP along III-III line of FIG. 2. A circuit layer 11 is provided on the substrate 10 described above. The circuit layer 11 includes various circuits and lines such as the pixel circuit 1, the scanning lines G, the signal lines S, and the power lines PL shown in FIG. 1. The circuit layer 11 is covered with an organic insulating layer 12. The organic insulating layer 12 functions as a planarization film planarizing irregularities formed by the circuit layer 11.

Each of the lower electrodes LE1, LE2, and LE3 is provided on the organic insulating layer 12. The rib layer 5 is provided on the organic insulating layer 12 and the lower electrodes LE1, LE2, and LE3. End portions of each of the lower electrodes LE1, LE2, and LE3 are covered with the rib layer 5.

The partition 6 includes a conductive lower portion 61 provided on the rib layer 5 and an upper portion 62 provided on the lower portion 61. The upper portion 62 has the width greater than that of the lower portion 61. This configuration causes both end portions of the upper portion 62 to protrude relative to the side surfaces of the lower portion 61. That is, the partition 6 has an overhang shape in which both end portions of the upper portion 62 protrude relative to the side surfaces of the lower portion 61.

In the example of FIG. 3, the lower portion 61 has the bottom layer 63 and the stem layer 64. The bottom layer 63 is thinner than the stem layer 64 and is located between the stem layer 64 and the rib layer 5. Both end portions of the bottom layer 63 respectively protrude relative to both side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the respective organic layers OR1, OR2, and OR3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

The sealing layers SE11, SE12, and SE13, which cover the respective stacked films FL1, FL2, and FL3 are provided in the respective subpixels SP1, SP2, and SP3. More specifically, the sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example of FIG. 3, the end portions of the sealing layers SE11 and SE12 overlap each other above the partition 6 between the subpixels SP1 and SP2 in the Z-direction. Further, the end portions of the sealing layers SE11 and SE13 overlap each other above the partition 6 between the subpixels SP1 and SP3 in the Z-direction. The configuration is not limited to this example. The end portions of the sealing layers SE11, SE12, and SE13 may be spaced apart from each other above the partition 6.

For example, gaps are formed between the respective sealing layers SE11, SE12, and SE13 and the upper portion 62 of the partition 6. The stacked films FL1, FL2, and FL3 may be provided in at least part of these gaps.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

In the present embodiment, a touch detection electrode 7 for detecting touch operations by a user is provided on the sealing layer SE2. The touch detection electrode 7 has the same shape as the partition 6 in plan view.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed, for example, of silver and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z direction. The organic layers OR1, OR2, and OR3 each may comprise other structures such as a tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

For example, each of the bottom layer 63 and the stem layer 64 of the partition 6 is formed, for example, of a metal material. For the metal material of the bottom layer 63, for example, molybdenum, titanium, titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

For example, the upper portion 62 of the partition 6 includes a stacked layer structure comprising a lower layer formed of a metal material and an upper layer formed of a conductive oxide. In this case, for the metal material of the lower layer, titanium, a titanium nitride, molybdenum, tungsten, a molybdenum-tungsten alloy, or a molybdenum-niobium alloy may be used. Further, for a conductive oxide of the upper layer, an ITO or an IZO may be used. The upper portion 62 may comprise three or more layers. Alternatively, the upper portion 62 may be formed of a single layer. The upper portion 62 may further include a layer formed of an insulating material.

Common voltage is applied to the partition 6. This common voltage is applied to each of the upper electrodes UE1, UE2, and UE3 in contact with the lower portions 61. Pixel voltages according to the video signals of the signal lines S are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. More specifically, when a potential difference is formed between the lower electrode LE1 and the upper electrode UE1, the light emitting layer of the organic layer OR1 emits light in the blue wavelength range. When a potential difference is formed between the lower electrode LE2 and the upper electrode UE2, the light emitting layer of the organic layer OR2 emits light in the green wavelength range. When a potential difference is formed between the lower electrode LE3 and the upper electrode UE3, the light emitting layer of the organic layer OR3 emits light in the red wavelength range.

In another example, the light emitting layers of the organic layers OR1, OR2, and OR3 may emit light of the same color (for example, white). In this case, the display device DSP may comprise a color filter that converts the light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

The touch detection electrode 7 is formed, for example, of a metal material and has light-shielding properties. The touch detection electrode 7 may be a single layer structure or a multilayer structure. Various configurations may be applicable as the multilayer structure. For example, a three-layer structure of titanium, aluminum, and titanium (what is called a TAT) can be used.

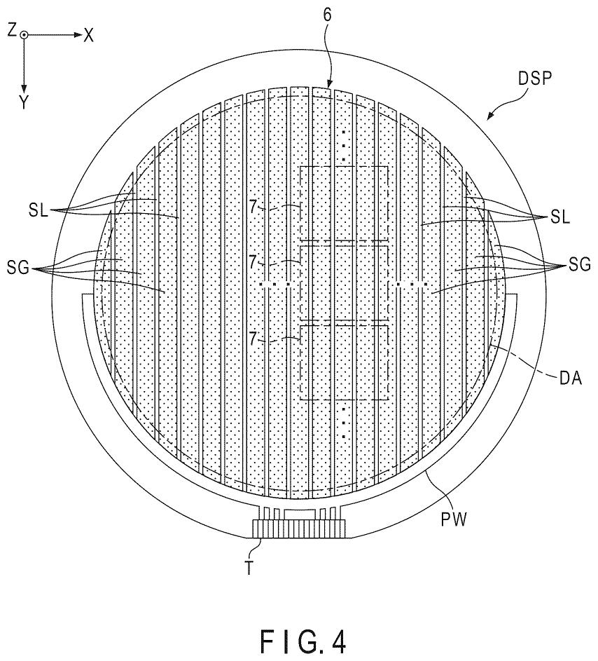

FIG. 4 is a schematic plan view showing some elements of the display device DSP. The plurality of slits SL shown in FIG. 2 split the partition 6 into the plurality of segments SG. FIG. 4 schematically shows the slits SL and the segments SG. For example, when the slits SL are located on both sides of the pixel PX in the X-direction as shown in FIG. 2, more slits SL are formed in the display area DA.

At least some of the plurality of segments SG are connected to each other by the connection portion CT crossing the slits SL as shown in FIG. 2. In contrast, the connection portion CT may not be provided in some of the slits SL.

Each of the slits SL contributes to increasing the transmittance of the display device DSP. Thus, for example, when an optical sensor is provided on the rear surface of the display device DSP, the detection performance of the sensor can be increased.

Further, as a specific aspect of the display device DSP, a configuration in which antennas are arranged on the rear surface and the short-range wireless communication is achieved through these antennas is assumed. In this form of use, the magnetic field during the communication may generate an eddy current in the partition 6, decreasing the signal strength. In this case, a slit SL having no connection portion CT can suppress the generation of an eddy current having the size great enough to spread in the entire display area DA. As a result, this slit SL can suppress decreases in the signal strength.

Each of the segments SG is connected to a power supply line PW provided in the surrounding area SA. The power supply line PW is connected to the terminal portion T. Common voltage is applied to each of the segments SG from the terminal portion T via the power supply line PW.

The plurality of touch detection electrodes 7 are aligned in the display area DA. These touch detection electrodes 7 are connected to the terminal portion T via lines. When an object such as a user's finger contacts or becomes close to the display area DA, a capacitance between the object and the touch detection electrode 7 varies. Then, a signal in response to this variation is output from the touch detection electrode 7 to the terminal portion T. The detection method using the touch detection electrode 7 is not limited to this example.

FIG. 5 is a schematic plan view showing configuration examples applicable to the partition 6, the sealing layers SE11, SE12, and SE13, and the touch detection electrode 7 according to the present embodiment. This figure shows the partition 6 with a dotted pattern and the touch detection electrode 7 with a hatched pattern.

FIG. 5 shows four segments SG1, SG2, SG3, and SG4 (the first to fourth segments) arranged in the X-direction, which constitute part of the partition 6. These segments SG1, SG2, SG3, and SG4 are separated from each other by three slits SL.

The segments SG1 and SG2 are connected to each other by the plurality of connection portions CT (one of them is shown in FIG. 5). The segments SG3 and SG4 are connected to each other by the plurality of connection portions CT. In contrast, the segments SG2 and SG3 are connected to each other by the connection portion CT. In the following descriptions, the slits SL in which the connection portions CT are provided are referred to as slits SLa (the first slits) such as the slits SL between the segments SG1 and SG2 and between the segments SG3 and SG4. In the following descriptions, the slit SL in which no connection portion CT is provided is referred to as a slit SLb (the second slit) such as the slit SL between the segments SG2 and SG3.

In the example of FIG. 5, the connection portion CT is provided at the position aligned with the subpixel SP3 in the X-direction. The connection portion CT may be aligned with all of the subpixels SP3 of the segments SG2 and SG4. Alternatively, the connection portion CT may be aligned with only some of the subpixels SP3.

In the example of FIG. 5, the sealing layers SE11, SE12, and SE13 located on the segment SG2 have the same shape as those shown in FIG. 2, respectively. That is, the end portions of the sealing layers SE12 and SE13 entirely overlap the partition 6, and parts of the end portion of the sealing layer SE11 is located in the slit SLa.

In contrast, in the segment SG3, the end portion of the sealing layers SE11 overlaps the partition 6 around its entire circumference, and part of the end portion of the sealing layer SE13 is located in the slit SLb. In the same manner as the segment SG2, the end portion of the sealing layer SE12 entirely overlaps the partition 6.

Here, the pixel shown in FIG. 5 including the sealing layers SE11, SE12, and SE13 of the segment SG2 is referred to as a pixel PX1. Similarly, the pixel shown in FIG. 5 including the sealing layers SE11, SE12, and SE13 of the segments SG3 is referred to as a pixel PX2. For example, in the display area DA, the pixels PX1 and PX2 are alternately arranged in the X-direction. Alternatively, the pixels PX1 and PX2 may be alternately arranged in the Y-direction.

The most part of the detection electrode 7 is constituted by a straight portion thinner than the partition 6. For example, the touch detection electrode 7 includes a straight portion La extending in the X-direction between two subpixels SP2 adjacent to each other in the Y-direction, and straight portions Lb and Lc extending in the X-direction between the subpixels SP1 and SP3 adjacent to each other in the Y-direction. The straight portion Lb and the straight portion La are arranged at a distance in the X-direction. The straight portion Lc has the width greater than those of the straight portions La and Lb.

Further, the touch detection electrode 7 has a first portion P1, a second portion P2, and a third portion P3 each located in the vicinity of the slits SLa. The first portion P1 overlaps the segment SG1. The second portion P2 overlaps the segment SG2.

The first portion P1 is connected to the straight portion La overlapping the segment SG1 and extends in the Y-direction along the slits SLa (the extending direction of the slits SLa). The second portion P2 is connected to the straight portion Lc overlapping the segment SG2 and extends in the Y-direction along the slits SLa. The third portion P3 connects the first portion P1 and the second portion P2 to each other. The third portion P3 has the width greater than the first portion P1 and the second portion P2 and entirely overlaps the connection portion CT crossing the slits SLa. Part of the connection portion CT may be exposed from the third portion P3.

Further, the touch detection electrode 7 has a fourth portion P4, a fifth portion P5, and a sixth portion P6 each located in the vicinity of the slit SLb. The fourth portion P4 overlaps the segment SG2. The fifth portion P5 overlaps the segment SG3.

The fourth portion P4 is connected to the straight portion La overlapping the segment SG2 and extends in the Y-direction along the slit SLb (the extending direction of the slit SLb). The fifth portion P5 is connected to the straight portion Lc overlapping the segment SG3 and extends in the Y-direction along the slit SLb. The sixth portion P6 connects the fourth portion P4 and the fifth portion P5 to each other. The sixth portion P6 has the width greater than the fourth portion P4 and the fifth portion P5 and entirely overlaps the slit SLb.

For example, the fourth portion P4, the fifth portion P5, and the sixth portion P6 have the same shape as the respective first portion P1, the second portion P2, and the third portion P3. However, at least one of these portions may have a shape different from the others.

For example, the first portion P1, the second portion P2, and the third portion P3 are provide for all of the connection portions CT. The fourth portion P4, the fifth portion P5, and the sixth portion P6 do not overlap the connection portion CT but are provided at the positions aligned with the first portion P1, the second portion P2, and the third portion P3 in the X-direction. This configuration can increase the regularity of the pattern of the touch detection electrode 7 irrespective of the existence of the connection portion CT.

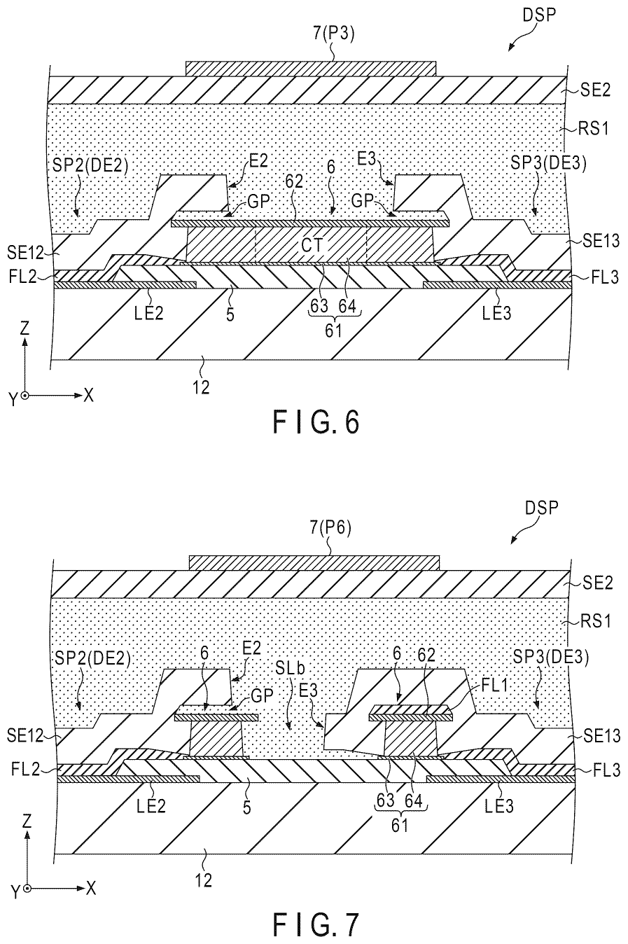

FIG. 6 is a schematic cross-sectional view of the display device DSP along VI-VI line of FIG. 5. FIG. 7 is a schematic cross-sectional view of the display device DSP along VII-VII line of FIG. 5. These figures omit illustration of elements under the organic insulating layer 12 and elements above the sealing layer SE2 and the touch detection electrode 7.

As shown in FIG. 6, the connection portion CT has the lower portion 61 (the bottom layer 63 and the stem layer 64) and the upper portion 62 in the same manner as the other parts of the partition 6. An end portion E2 of the sealing layer SE12 and an end portion E3 of the sealing layer SE13 are located above the partition 6. The third portion P3 of the touch detection electrode 7 faces the partition 6 (the connection portion CT) via the resin layer RS1 and the sealing layer SE2.

As shown in FIG. 7, the side portion along the slit SL (the slit SLb) of the partition 6 has an overhang shape in which the upper portion 62 protrudes relative to the side surface of the stem layer 64. For example, the rib layer 5 is not open in the slit SLb. In the example of FIG. 7, the end portion E3 of the sealing layer SE13 is located in the slit SLb. The sixth portion P6 of the touch detection electrode 7 faces the partition 6 via the resin layer RS1 and the sealing layer SE2 and overlaps the slit SLb in the Z-direction.

In each of FIG. 6 and FIG. 7, gaps GP are formed under the end portions E2 and E3. Though not illustrated in FIG. 6 and FIG. 7, the gap GP is formed under the end portion of the sealing layer SE11 as well. At least part of the gap GP is filled with the resin layer RS1. As described in the explanation on FIG. 2, the stacked films FL1, FL2, and FL3 may be provided in at least part of these gaps GP.

The gap GP is formed by removing the stacked films FL1, FL2, and FL3 originally formed in the manufacturing process of the display device DSP. Specifically, the stacked films FL2 and FL3 under the end portions of the sealing layers SE11, SE12, and SE13 are eroded by various etching solutions to be void. In one example, the stacked film FL1 and the sealing layer SE11 are formed first, the stacked film FL2 and the sealing layer SE12 are formed second, and the stacked film FL3 and the sealing layer SE13 are formed last. In this case, among the stacked films FL1, FL2, and FL3, the stacked film FL1 formed first is most prone to removal, while the stacked film FL3 formed last is least prone to removal. Thus, at the positions shown as the gaps GP, the stacked films FL1 and FL2 may potentially be removed but the stacked film FL3 may potentially remain in some cases.

Further, if the connection portion CT is provided at the position aligned with the subpixel SP1 in the X-direction in the configuration of FIG. 5, the sealing layer SE11 of the segment SG2 partially covers the connection portion CT. In this case, the stacked film FL on the partition 6 around the subpixel SP1 also is prone to erosion by etching solution and the like via the stacked film FL located on the connection portion CT. Thus, from the perspective of stably controlling the degree of removal of the stacked film FL formed first, the connection portion CT is preferably provided in the vicinity of the subpixel SP3 formed last as shown in FIG. 5.

Next, the following will describe effects of the present embodiment.

When the slit SLa with the connection portion CT and the slit SLb without the connection portion CT are both provided in the configuration in which the partition 6 is constituted by the segments SG as in the present embodiment, differences in appearance may occur between these slits SLa and SLb. Specifically, when external light enters the display area DA with all pixels PX not illuminated, reflection occurs at the connection portion CT in slit SLa but not in the slit SLb. Thus, a streak extending in the Y-direction may potentially be visually recognized by a user.

In contrast, in the present embodiment, the touch detection electrode 7 (the third portion P3) overlaps the connection portion CT. This configuration can suppress the unevenness in reflected light caused by the connection portion CT. Furthermore, a configuration in which the sixth portion P6 equivalent to the third portion P3 is provided in the slit SLb makes the reflected light from the touch detection electrode 7 in each of the slits SLa and SLb have the same pattern. Thus, the unevenness in reflected light caused by the touch detection electrode 7 can be suppressed as well.

The present embodiment can achieve various suitable effects in addition to the above effects.

### Second Embodiment

The following will describe on the second embodiment. Unless otherwise specified, the configuration of the display device DSP can be the same as those of the first embodiment.

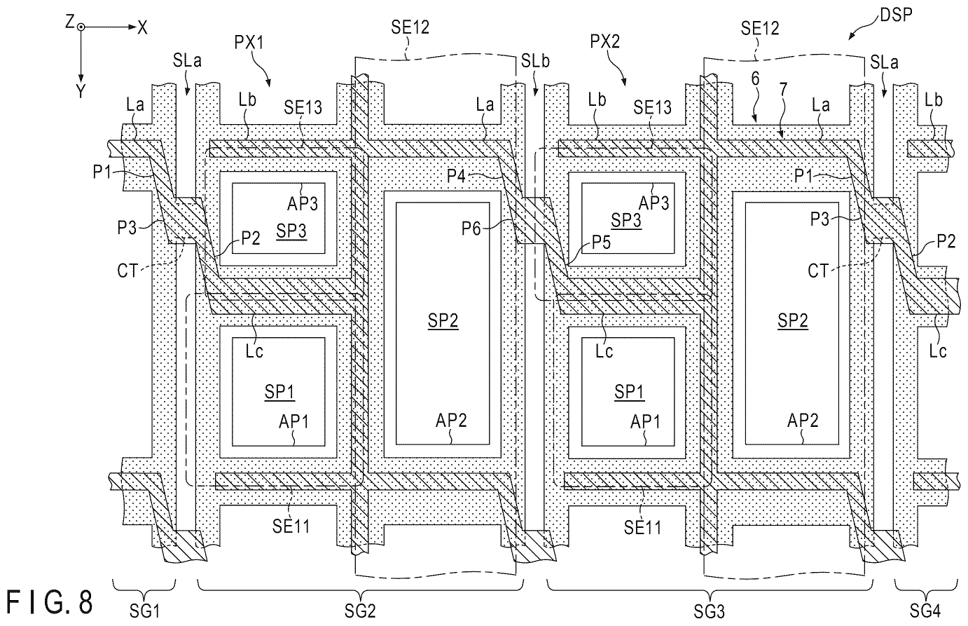

FIG. 8 is a schematic plan view showing configuration examples applicable to the partition 6, the sealing layers SE11, SE12, and SE13, and the touch detection electrode 7 according to the second embodiment. In the same manner as FIG. 5, this figure shows the partition 6 with a dotted pattern and the touch detection electrode 7 with a hatched pattern.

In the present embodiment, the first portion P1, the second portion P2, the fourth portion P4, and the fifth portion P5 extend in a direction intersecting the X-direction and the Y-direction (the extending direction of the slit). In the example of FIG. 8, the first portion P1, the second portion P2, the fourth portion P4, and the fifth portion P5 have the same extending direction. At least one of these portions may have an extending direction different from the extending direction of the others.

When the formation position of the touch detection electrode 7 is slightly offset relative to the partition 6 in the X-direction in the configuration in which the first portion P1, the second portion P2, the fourth portion P4, and the fifth portion P5 extend in the Y-direction on both sides of the slit SL as in the configuration shown in FIG. 5, these portions may potentially block a large area of the slit SL. In this case, the transmittance of the display device DSP decreases.

In contrast, in the present embodiment, the first portion P1, the second portion P2, the fourth portion P4, and the fifth portion P5 are inclined relative to the extending direction of the slit SL. Thus, even when the formation position of the touch detection electrode 7 is slightly offset relative to the partition 6 in the X-direction, the area in which these portions and the slit SL overlap can be minimized.

### Third Embodiment

The following will describe on the third embodiment. Unless otherwise specified, the configuration of the display device DSP can be the same as those of the first embodiment.

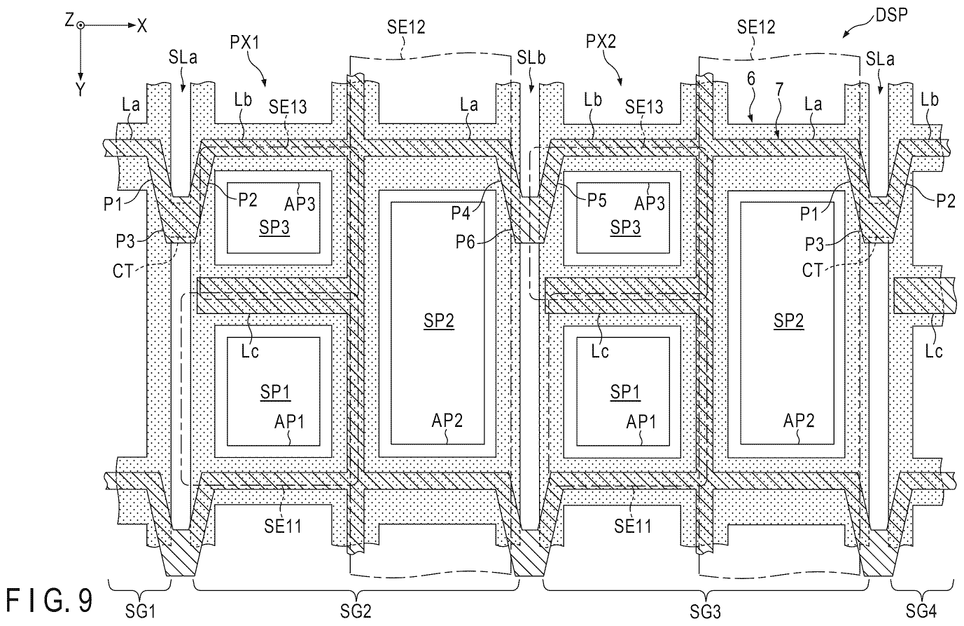

FIG. 9 is a schematic plan view showing configuration examples applicable to the partition 6, the sealing layers SE11, SE12, and SE13, and the touch detection electrode 7 according to the third embodiment. In the same manner as FIG. 5, this figure shows the partition 6 with a dotted pattern and the touch detection electrode 7 with a hatched pattern.

In the same manner as the second embodiment, the first portion P1, the second portion P2, the fourth portion P4, and the fifth portion P5 are inclined relative to the Y-direction (the extending direction of the slit SL) in the present embodiment. The first portion P1 and the second portion P2 have inclination angles different from each other. Further, the fourth portion P4 and the fifth portion P5 have inclination angles different from each other.

More specifically, the first portion P1 and the second portion P2 are symmetrical about the axis of the slit SLa (the centerline in the X direction). Similarly, the fourth portion P4 and the fifth portion P5 are symmetrical about the axis of the slit SLb (the centerline in the X direction).

In the present embodiment, the second portion P2 and the fifth portion P5 are connected to the straight portion Lb. Thus, the first portion P1, the second portion P2, and the third portion P3 form a V-shape. Similarly, the fourth portion P4, the fifth portion P5, and the sixth portion P6 form a V-shape.

In the same manner as the second embodiment, even when the formation position of the touch detection electrode 7 is slightly offset relative to the partition 6 in the X-direction, the configuration of the present embodiment can minimize the area in which these portions and the slit SL overlap.

### Fourth Embodiment

The following will describe on the fourth embodiment. Unless otherwise specified, the configuration of the display device DSP can be the same as those of the embodiments.

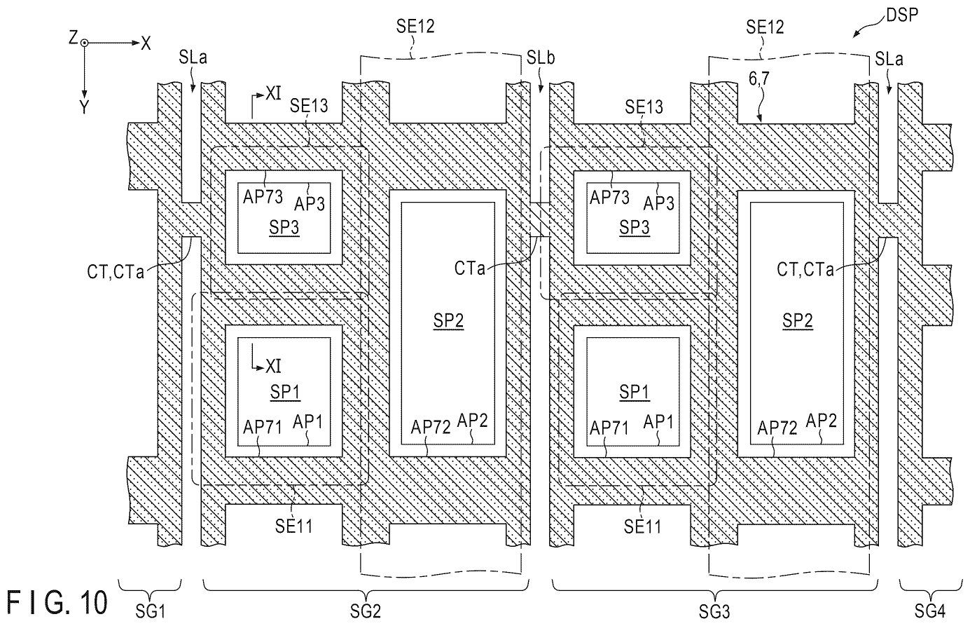

FIG. 10 is a schematic plan view showing configuration examples applicable to the partition 6, the sealing layers SE11, SE12, and SE13, and the touch detection electrode 7 according to the fourth embodiment. In the same manner as FIG. 5, this figure shows the partition 6 with a dotted pattern and the touch detection electrode 7 with a hatched pattern.

In the present embodiment, the touch detection electrode 7 has a shape entirely overlapping the partition 6. Here, “entirely overlapping” includes not only a shape where the touch detection electrode 7 completely overlaps the entire partition 6 in plan view, but also a shape where a small part (for example, within a range of 3.0 μm or less) of the partition 6 is exposed from the touch detection electrode 7 while the remaining large portion overlaps the touch detection electrode 7.

The touch detection electrode 7 includes an electrode aperture AP71 overlapping the subpixel SP1, an electrode aperture AP72 overlapping the subpixel SP2, and an electrode aperture AP73 overlapping the subpixel SP3. Further, the touch detection electrode 7 includes a connection portion CTa overlapping the connection portion CT of the partition 6. In the example of FIG. 10, the connection portion CTa is provided in the slit SLb not having the connection portion CT as well.

As described above, the stacked films FL1, FL2, and FL3 on the partition 6 may potentially be removed in the manufacturing process of the display device DSP. The stacked films FL1, FL2, and FL3 include the respective upper electrodes UE1, UE2, and UE3 formed of metal materials such as an alloy of magnesium and silver (MgAg) and the like. Thus, differences in the degree of removal of the stacked films FL1, FL2, and FL3 at various locations may potentially degrade the appearance of reflected light.

In contrast, as in the present embodiment, the touch detection electrode 7 having a shape entirely overlapping the partition 6 can suppress deterioration in appearance caused by differences in the degree of removal of the stacked films FL1, FL2, and FL3.

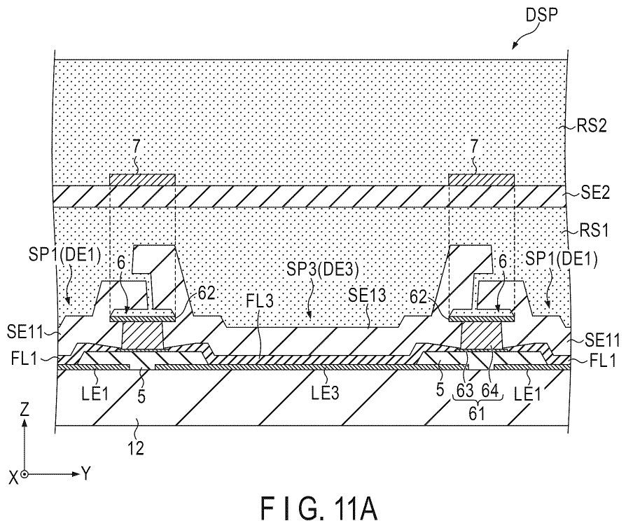

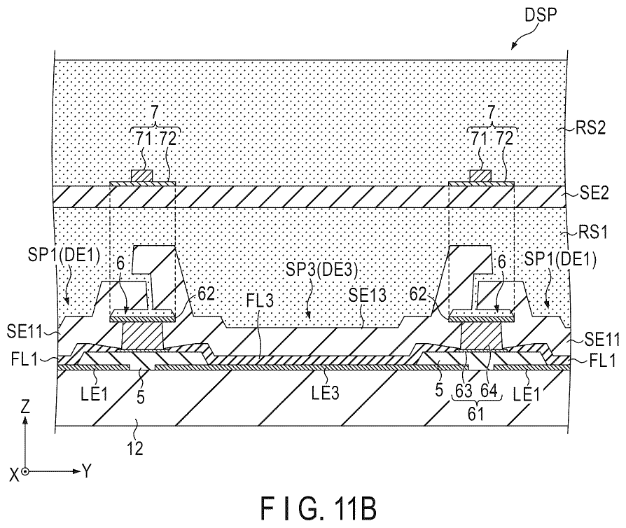

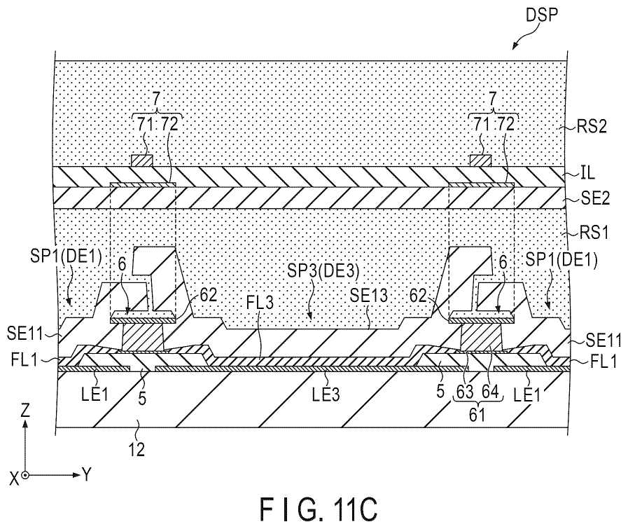

FIG. 11A to FIG. 11C are schematic cross-sectional views showing configurations applicable to the display device DSP according to the present embodiment. These cross-sectional views correspond to the cross sections along XI-XI line of FIG. 10.

In the same manner as the example shown in FIG. 3 and the like, the touch detection electrode 7 is provided on the sealing layer SE2 in FIG. 11A. For example, the touch detection electrode 7 has the same width as the upper portion 62 of the partition 6.

In FIG. 11B, the touch detection electrode 7 has a first layer 71 and a second layer 72. The second layer 72 is provided on the sealing layer SE2. The first layer 71 is provided on the second layer 72. That is, the first layer 71 contacts the upper surface of the second layer 72. The first layer 71 and the second layer 72 are covered with the resin layer RS2.

The second layer 72 has the thickness smaller than the first layer 71. Further, the second layer 72 has the width greater than the first layer 71. The first layer 71 and the second layer 72 are provided such that their centers in the width direction are coincident with each other. The outer shape of the touch detection electrode 7 shown in FIG. 10 corresponds to the outer shape of the second layer 72.

The first layer 71 is conductive and is formed, for example, of a metal material. The first layer 71 may be a single layer structure or a multilayer structure. The second layer 72 at least has light-shielding properties. The second layer 72 may be formed of a metal material to further have conductivity.

For example, the first layer 71 has a third layer structure of titanium, aluminum, and titanium. Further, the second layer 72 is formed of titanium. For example, the thickness of the first layer 71 is 300 nm or more. Further, for example, the thickness of the second layer 72 is 200 nm or less. However, the configuration and the thickness of each of the first layer 71 and the second layer 72 are not limited to those illustrated here as the examples.

In FIG. 11C as well, the touch detection electrode 7 has the first layer 71 and the second layer 72. Further, an insulating layer IL is provided between the first layer 71 and the second layer 72. For example, the insulating layer IL is formed of an inorganic insulating material such as a silicon nitride, a silicon oxide, or a silicon oxynitride.

In the configuration in FIG. 11C, the first layer 71 and the second layer 72 preferably have the same potential. Here, the first layer 71 and the second layer 72 may be connected to each other, for example, via a contact hole provided in the insulating layer IL. This contact hole may be provided in the display area DA or the surrounding area SA.

In the present embodiment, the width of the touch detection electrode 7 is as great as that of the partition 6. Thus, when the touch detection electrode 7 is formed thickly in the configuration of FIG. 11A, light inclined with respect to the Z-direction of light emitted from the display elements DE1, DE2, and DE3 may be blocked by the touch detection electrode 7. Thus, the viewing angle characteristics may be potentially reduced. In contrast, a thin touch detection electrode 7 may potentially decrease the detection performance.

With respect to this point, the configurations of FIG. 11B and FIG. 11C can maintain the detection performance by using the thick and narrow first layer 71 and also improve the appearance of the reflected light by using the thin and wide second layer 72. Furthermore, the thin second layer 72 makes light emitted from the display elements DE1, DE2, and DE3 and inclined with respect to the Z-direction less likely to be blocked. This configuration can suppress the degradation in the viewing angle characteristics.

### Fifth Embodiment

The following will describe on the fifth embodiment. Unless otherwise specified, the configuration of the display device DSP can be the same as those of the embodiments.

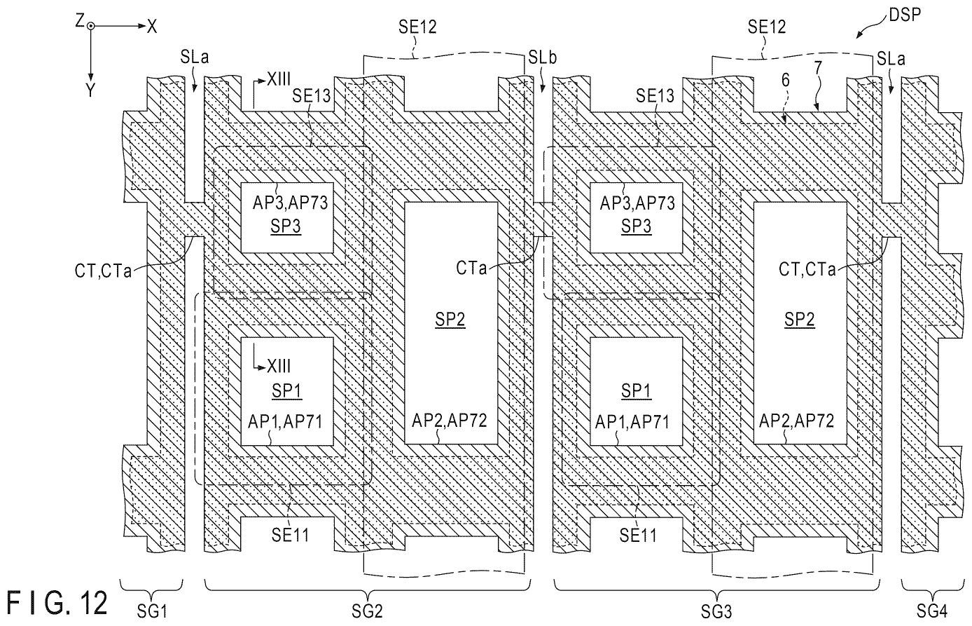

FIG. 12 is a schematic plan view showing configuration examples applicable to the partition 6, the sealing layers SE11, SE12, and SE13, and the touch detection electrode 7 according to the fifth embodiment. In the same manner as FIG. 5, this figure shows the partition 6 with a dotted pattern and the touch detection electrode 7 with a hatched pattern.

In the same manner as the fourth embodiment, the touch detection electrode 7 has a shape entirely overlapping the partition 6 in the present embodiment. Furthermore, in the present embodiment, the edge portions of the electrode apertures AP71, AP72, and AP73 substantially coincide with the edge portions of the respective pixel apertures AP1, AP2, and AP3. Here, “substantially coincide” includes not only cases where the edge portions of the electrode apertures AP71, AP72, and AP73 and the edge portions of the pixel apertures AP1, AP2, and AP3 perfectly coincide in plan view, but also cases where they are slightly misaligned (for example, by a few percent of the aperture width).

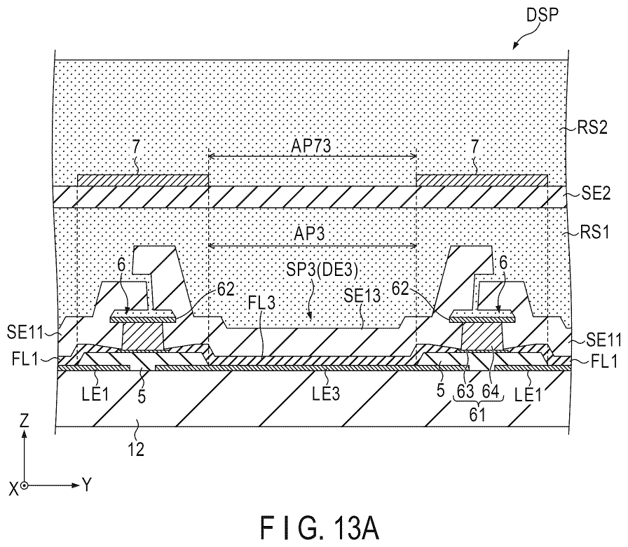

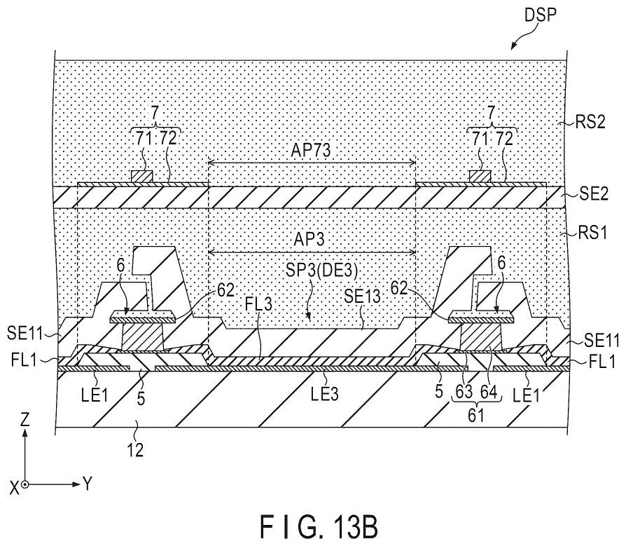

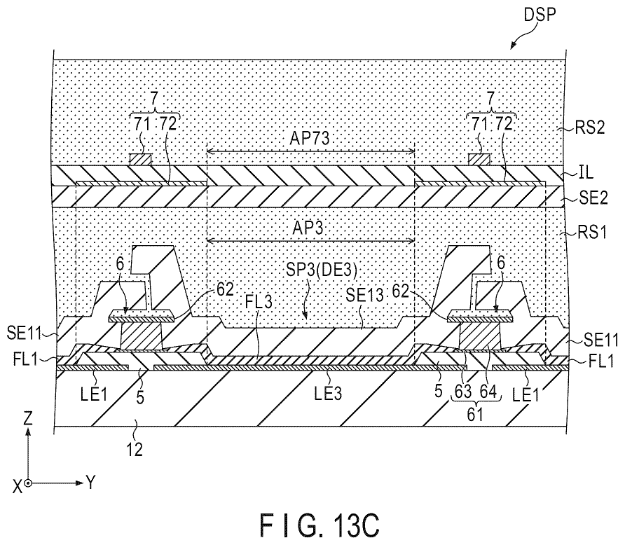

FIG. 13A to FIG. 13C are schematic cross-sectional views showing configurations applicable to the display device DSP according to the present embodiment. These cross-sectional views correspond to the cross sections along XIII-XIII line of FIG. 12.

In the same manner as the example shown in FIG. 11A, the touch detection electrode 7 is provided on the sealing layer SE2 in FIG. 13A. The touch detection electrode 7 has the same width as the rib layer 5 below the touch detection electrode 7.

In FIG. 13B and FIG. 13C, the touch detection electrode 7 has the first layer 71 and the second layer 72 as in the examples of FIG. 11B and FIG. 11C. Further, in FIG. 13C, the insulating layer IL is provided between the first layer 71 and the second layer 72. In all of these figures, the second layer 72 has the same width as the rib layer 5 below the second layer 72.

FIG. 13A to FIG. 13C show cross-sections crossing the subpixel SP3. These configurations may apply to the configuration of the partition 6 and the touch detection electrode 7 around the subpixels SP1 and SP2.

In the configuration of the present embodiment, the touch detection electrode 7 blocks light over a wider area than the configuration of the fourth embodiment. Thus, the configuration of the present embodiment can more effectively suppress degradation in appearance due to differences in the degree of removal of the stacked films FL1, FL2, and FL3.

All of the display devices that can be implemented by a person of ordinary skill in the art through arbitrary design changes to the display device described above as the embodiments of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, even if a person of ordinary skill in the art arbitrarily modifies each of the embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from each of the embodiments and are self-explanatory from the descriptions of the specification or can be arbitrarily conceived by a person of ordinary skill in the art are considered as the effects of the present invention as a matter of course.

What is claimed is:

1. A display device, comprising:
a display area including a plurality of subpixels;
a rib layer having a plurality of pixel apertures respectively located in the plurality of subpixels;
a partition surrounding each of the plurality of pixel apertures and including a conductive lower portion provided above the rib layer and an upper portion having an end portion protruding relative to a side surface of the lower portion;
a plurality of display elements respectively provided in the plurality of subpixels and each including an organic layer emitting light in response to a voltage application;
a plurality of first sealing layers formed of inorganic insulating materials and respectively covering the plurality of display elements; and
a touch detection electrode having light-shielding properties, provided above the partition and configured to detect operations with respect to the display area, wherein
the partition includes:
a first segment and a second segment separated from each other by a first slit; and
a connection portion crossing the first slit to connect the first segment and the second segment to each other, and
the touch detection electrode overlaps the connection portion in plan view.

2. The display device of claim 1, wherein
the touch detection electrode includes:
a first portion having a straight shape and overlapping the first segment in plan view;
a second portion having a straight shape and overlapping the second segment in plan view; and
a third portion overlapping the connection portion in plan view and connecting the first portion and the second portion to each other.

3. The display device of claim 2, wherein
the first portion and the second portion extend in an extending direction of the first slit.

4. The display device of claim 2, wherein
at least one of the first portion and the second portion extends in a direction intersecting the extending direction of the first slit.

5. The display device of claim 4, wherein
the first portion and the second portion extend in the same direction.

6. The display device of claim 4, wherein
the first portion, the second portion, and the third portion form a V-shape.

7. The display device of claim 2, wherein
the third portion has a width greater than each of the first portion and the second portion.

8. The display device of claim 2, wherein
the third portion overlaps the entire connection portion.

9. The display device of claim 2, wherein
the partition further includes a third segment separated from the second segment by a second slit, and
the touch detection electrode includes:
a fourth portion having a straight shape and overlapping the second segment in plan view;
a fifth portion having a straight shape and overlapping the third segment in plan view; and
a sixth portion overlapping the second slit in plan view and connecting the fourth portion and the fifth portion to each other.

10. The display device of claim 9, wherein
the second segment and the third segment are not connected to each other by a connection portion.

11. The display device of claim 9, wherein
the fourth portion and the first portion extend in the same direction, and
the fifth portion and the second portion extend in the same direction.

12. The display device of claim 1, further comprising:
a resin layer covering the partition and the plurality of first sealing layers; and
a second sealing layer formed of an inorganic insulating material and covering the resin layer; and
the touch detection electrode is provided on the second sealing layer.

13. A display device, comprising:
a display area including a plurality of subpixels;
a rib layer having a plurality of pixel apertures respectively located in the plurality of subpixels;
a partition surrounding each of the plurality of pixel apertures and including a conductive lower portion provided above the rib layer and an upper portion having an end portion protruding relative to a side surface of the lower portion;
a plurality of display elements respectively provided in the plurality of subpixels and each including an organic layer emitting light in response to a voltage application;
a plurality of first sealing layers formed of inorganic insulating materials and respectively covering the plurality of display elements; and
a touch detection electrode having light-shielding properties, provided above the partition and configured to detect operations with respect to the display area, wherein
the touch detection electrode has a shape entirely overlapping the partition in plan view.

14. The display device of claim 13, wherein
the touch detection electrode has an electrode aperture overlapping the pixel aperture, and
an edge portion of the electrode aperture and an edge portion of the pixel aperture substantially coincide with each other in plan view.

15. The display device of claim 13, wherein
the touch detection electrode comprises:
a conductive first layer; and
a light-shielding second layer thinner and wider than the first layer.

16. The display device of claim 15, wherein
the first layer contacts an upper surface of the second layer.

17. The display device of claim 16, further comprising:
a resin layer covering the partition and the plurality of first sealing layers; and
a second sealing layer formed of an inorganic insulating material and covering the resin layer, wherein
the second layer is provided on the second sealing layer.

18. The display device of claim 15, further comprising:
an insulating layer provided between the first layer and the second layer.

19. The display device of claim 18, further comprising:
a resin layer covering the partition and the plurality of first sealing layers; and
a second sealing layer formed of an inorganic insulating material and covering the resin layer, wherein
the second layer is provided on the second sealing layer,
the insulating layer covers the second layer and the second sealing layer, and
the first layer is provided on the insulating layer.

20. The display device of claim 15, wherein
the first layer is thicker than the second layer.
